(19) United States
(12) Patent Application Publication
(10) Pub. No.: US 2013/0026616 A1
(43) Pub. Date: Jan. 31, 2013

(54) POWER DEVICE PACKAGE MODULE AND MANUFACTURING METHOD THEREOF

(71) Applicants: Suk Ho LEE, Soul (KR); Jae Cheon DOH, Chungcheongnam-do (KR); Young Hoon KWAK, Gyeonggi-do (KR); Tae Hoon KIM, Gyeonggi-do (KR); Tao Jyun KIM, Seoul (KR); Young Ki LEE, Gyeonggi-do (KR)

(72) Inventors: Suk Ho LEE, Soul (KR); Jae Cheon DOH, Chungcheongnam-do (KR); Young Hoon KWAK, Gyeonggi-do (KR); Tae Hoon KIM, Gyeonggi-do (KR); Tao Jyun KIM, Seoul (KR); Young Ki LEE, Gyeonggi-do (KR)

(73) Assignee: SAMSUNG ELECTRO-MECHANICS CO., LTD.

(21) Appl. No.: 13/557,834

(22) Filed: Jul. 25, 2012

(30) Foreign Application Priority Data
Jul. 25, 2011 (KR) 10-2011-0073716

(51) Int. Cl. H01L 23/495; H01L 21/60

(52) U.S. Cl. 257/675; 438/122; 257/E23.051; 257/E21.506

(57) ABSTRACT

The present invention relates to a power device package module and a manufacturing method thereof. In one aspect of the present invention, a power device package module includes: a control unit a first lead frame, a control chip and a first coupling portion that are mounted on a first substrate, wherein the first lead frame and the first coupling portion are electrically connected to the control chip, and individually molded; and a power unit including a second lead frame, a power chip and a second coupling portion that are mounted on a second substrate, wherein the second lead frame and the second coupling portion are electrically connected to the power chip, and individually molded, wherein the individually molded control unit and power unit are coupled by the first coupling portion and the second coupling portion.

### CROSS-REFERENCE TO RELATED APPLICATIONS

Claim and incorporate by reference domestic priority application and foreign priority application as follows:

### Cross Reference to Related Application

This application claims the benefit under 35 U.S.C. Section 119 of Korean Patent Application Serial No. 10-2011-0073716, entitled filed Jul. 25, 2011, which is hereby incorporated by reference in its entirety into this application.

### BACKGROUND OF THE INVENTION

1. Field of the Invention

The present invention relates to a power device package module and a manufacturing method thereof, and more particularly, to a power device package module in which a control unit and a power unit are individually molded and connected to each other, and a manufacturing method thereof.

2. Description of the Related Art

In recent times, according to the rapidly changing market demand of electronic devices such as consumer electronics, there has been a need for development of a new generation power module that implements miniaturization, multi-function, and high performance and shows high reliability, high density, and improved thermal performance compared to a conventional power module.

For example, a conventional power device package module has a structure in which a control IC part and a power module part are connected by an Al wire in the integrally molded one package. In this method, for bonding of the control IC part, a PCB should be inserted, and EMC molding is performed after Al bonding is separately performed.

U.S. Laid-open Patent Publication No. US 2010/0226095 A1 discloses this conventional technology. US 2010/0226095 A1 discloses the technology in which the power unit and the control unit are molded using one lead frame and finally connected by a wire.

### SUMMARY OF THE INVENTION

The above-described conventional method has problems that processes become difficult and the entire package is treated as bad when one of the control unit and the power unit is damaged. Further, there is a problem of thermal interaction when the control unit and the power unit are manufactured into one package.

The present invention has been invented in order to overcome the above-described problems and it is, therefore, an object of the present invention to provide a power device package module and a manufacturing method thereof that are capable of obtaining one power module by individually packaging a power unit and a control unit through a primary packaging process and connecting the two packages.

In accordance with one aspect of the present invention to achieve the object, there is provided a power device package module including: a control unit including a first substrate, a first lead frame, a control chip and a first coupling portion and individually molded so that the first coupling portion and an external connection part of the first lead frame are exposed to the outside, wherein a first lead frame and a control chip electrically connected to the first lead frame are mounted on the first substrate and the first coupling portion formed at one side of the first substrate to be electrically connected to the control chip; and a power unit including a second substrate, a second lead frame, a power chip and a second coupling portion and individually molded so that the second coupling portion and an external connection part of the second lead frame are exposed to the outside, wherein the second lead frame and the power chip electrically connected to the second lead frame are mounted and the second coupling portion formed at one side of the second substrate to be electrically connected to the power chip, wherein the individually molded control unit and power unit are coupled by the first coupling portion and the second coupling portion.

In accordance with an embodiment of the present invention, the power unit includes a heat sink attached to the other surface of the second substrate.

In accordance with another embodiment of the present invention, the power device package module further includes a conductive coupling frame unit which is coupled with the first and second coupling portions, and the control unit and the power unit are coupled by the coupling frame unit.

In accordance with another embodiment of the present invention, one of the first coupling portion and the second coupling portion is formed to have a through-hole structure, the other is formed to have a projection structure, and the through-hole structure and the projection structure are coupled with each other. In accordance with another embodiment, the through-hole is formed in the first or second substrate, and the projection structure is a portion of the first or second lead frame.

In accordance with another embodiment of the present invention, each of the first and second coupling portions is a portion of each of the first and second lead frames, and the first and second coupling portions are bonded by soldering. In accordance with another embodiment, at least one of the first and second coupling portions protrudes to the outside to form an external connection terminal.

Further, in accordance with another embodiment of the present invention, the control unit and the power unit are connected so that one surface of the first substrate on which the control chip is mounted and one surface of the second substrate on which the power chip is mounted are disposed in the same or opposite directions.

Further, in accordance with another embodiment of the present invention, the first substrate is a PCB substrate, the first lead frame is attached on the PCB, and the control chip is mounted on the first lead frame, wherein wire bonding is formed between the first lead frame and the first coupling portion.

In accordance with another embodiment of the present invention, the first or second substrate is formed by forming a seed layer on one surface of a ceramic plate and a metal layer on the seed layer, the first or second lead frame is attached on the metal layer by soldering, and the control chip or the power chip is mounted on the first or second lead frame, wherein wire bonding is formed between the first lead frame and the first coupling portion and between the second lead frame and the second coupling portion.

Further, in accordance with another embodiment of the present invention, the power chip includes an IGBT device and an FWD device, wherein the IGBT and FWD devices are individually mounted and connected in parallel by wire bonding.

Next, in accordance with another aspect of the present invention to achieve the object, there is provided a method of manufacturing a power device package module including: a control unit packaging step of packaging a control unit by mounting a first lead frame and a control chip on one surface of a first substrate, electrically connecting the control chip to the first lead frame, forming a first coupling portion at one side of the first substrate to be electrically connected to the control chip, and individually molding the control unit so that the first coupling portion and an external connection part of the first lead frame are exposed to the outside; a power unit packaging step of packaging a power unit by mounting a second lead frame and a power chip on one surface of a second substrate, electrically connecting the power chip to the second lead frame, forming a second coupling portion at one side of the second substrate to be electrically connected to the power chip, and individually molding the power unit so that the second coupling portion and an external connection part of the second lead frame are exposed to the outside; and a connecting step of connecting the packaged control unit and power unit by coupling the first coupling portion and the second coupling portion.

In accordance with an embodiment of the present invention, after the connecting step, the method of manufacturing a power device package module further includes a heat sink attaching step of attaching a heat sink to the other surface of the second substrate.

In accordance with another embodiment of the present invention, in the connecting step, the packaged control unit and power unit are connected by coupling a conductive coupling frame unit with the first and second coupling portions.

Further, in accordance with another embodiment of the present invention, one of the first coupling portion and the second coupling portion is formed to have a through-hole structure, the other is formed to have a projection structure, and in the connecting step, the through-hole structure and the projection structure are coupled with each other.

In accordance with another embodiment of the present invention, each of the first and second coupling portions is a portion of each of the first and second lead frames, and in the connecting step, the first and second coupling portions are bonded by soldering.

In accordance with another embodiment of the present invention, in the connecting step, the packaged control unit and power unit are connected so that one surface of the first substrate on which the control chip is mounted and one surface of the second substrate on which the power chip is mounted are disposed in the same or opposite directions.

Further, in accordance with another embodiment of the present invention, in the control unit packaging step and the power unit packaging step, wire bonding is performed to electrically connect between the control chip and the first lead frame, between the control chip and the first coupling portion, between the power chip and the second lead frame, and between the power chip and the second coupling portion.

In accordance with another embodiment, in the control unit packaging step or the power unit packaging step, a seed layer is formed on one surface of a ceramic plate, a metal layer is formed on the seed layer, the first or second lead frame is attached on the metal layer by soldering, and the control chip or the power chip is mounted on the first or second lead frame.

Although not explicitly described as one aspect of the present invention, embodiments of the present invention in accordance with possible various combinations of the above-described technical features can be apparently implemented by those skilled in the art.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a view roughly showing a power device package module in accordance with an embodiment of the present invention;

FIG. 2 is a view roughly showing a power device package module in accordance with another embodiment of the present invention;

FIG. 3 is a view roughly showing a power device package module in accordance with another embodiment of the present invention;

FIG. 4 is a view roughly showing a power device package module in accordance with another embodiment of the present invention;

FIG. 5 is a view roughly showing a power device package module in accordance with another embodiment of the present invention;

FIG. 6 is a view roughly showing a power device package module in accordance with another embodiment of the present invention;

FIG. 7 is a flowchart roughly showing a method of manufacturing a power device package module in accordance with an embodiment of the present invention;

FIG. 8 is a flowchart roughly showing a method of manufacturing a power device package module in accordance with another embodiment of the present invention; and

(a) to (e) of FIG. 9 are views roughly showing a method of manufacturing a power device package module in accordance with an embodiment of the present invention.

### DETAILED DESCRIPTION OF THE PREFERABLE EMBODIMENTS

Embodiments of the present invention to achieve the above-described objects will be described with reference to the accompanying drawings. In this description, the same elements are represented by the same reference numerals, and additional description which is repeated or limits interpretation of the meaning of the invention may be omitted.

In this specification, when an element is referred to as being “connected” or “coupled” to another element, it can be “directly” connected or coupled to the other element or connected or coupled to the other element with another element interposed therebetween, unless it is referred to as being “directly connected” or “directly coupled” to the other element. Further, in this specification, it should be understood that when an element is referred to as being “on”, “over”, “above”, “under”, or “below” another element, it can be “directly in contact with” the other element or in contact with the other element with another element interposed therebetween, unless it is referred to as being directly in contact with the other element. In addition, the relative terms such as “on”, “over”, “above”, “under”, or “below” can be used to describe the relation of one element to the other element. At this time, when the direction of the reference element is reversed or changed, it can be used as the meaning including the concept depending on the direction of the corresponding relative terms.

Although the singular form is used in this specification, it should be noted that the singular form can be used as the concept representing the plural form unless being contradictory to the concept of the invention or clearly interpreted otherwise.

It should be understood that the terms such as “having”, “including”, and “comprising” used herein do not preclude existence or addition of one or more other features or elements or combination thereof.

First, a power device package module in accordance with one aspect of the present invention will be specifically described with reference to the accompanying drawings. In describing embodiments of the power device package module in accordance with the present invention, although not directly described, embodiments of a method of manufacturing a power device package module, which will be described later, should be referred.

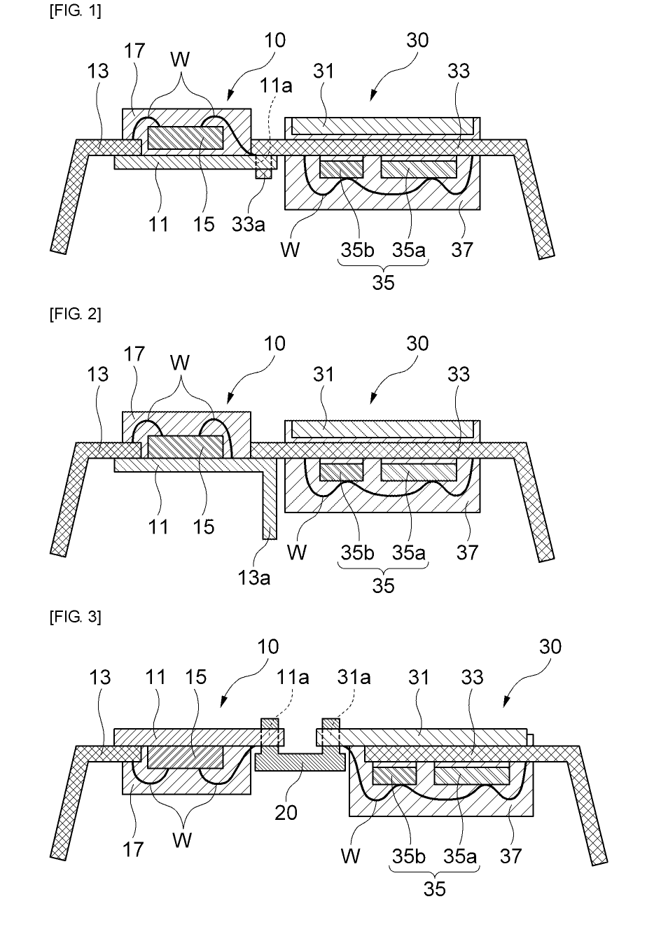

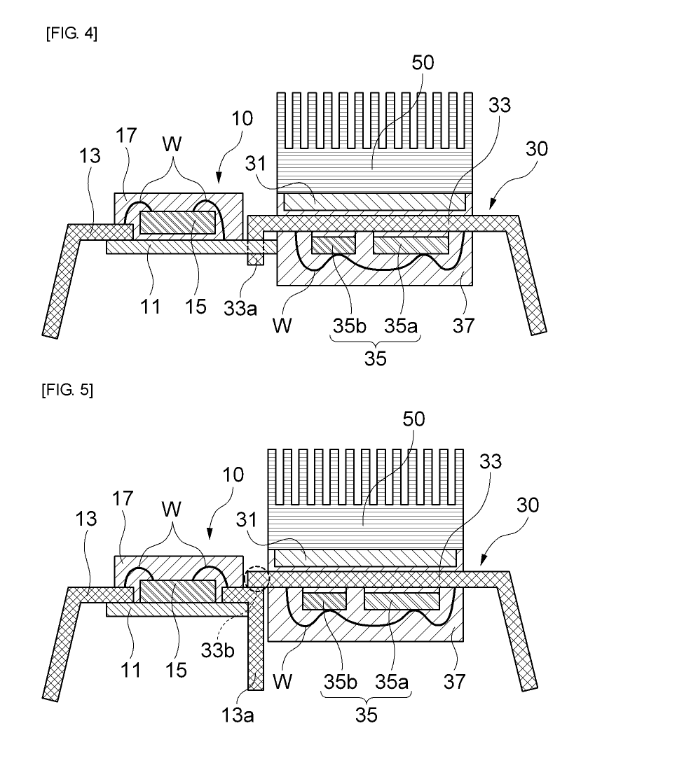

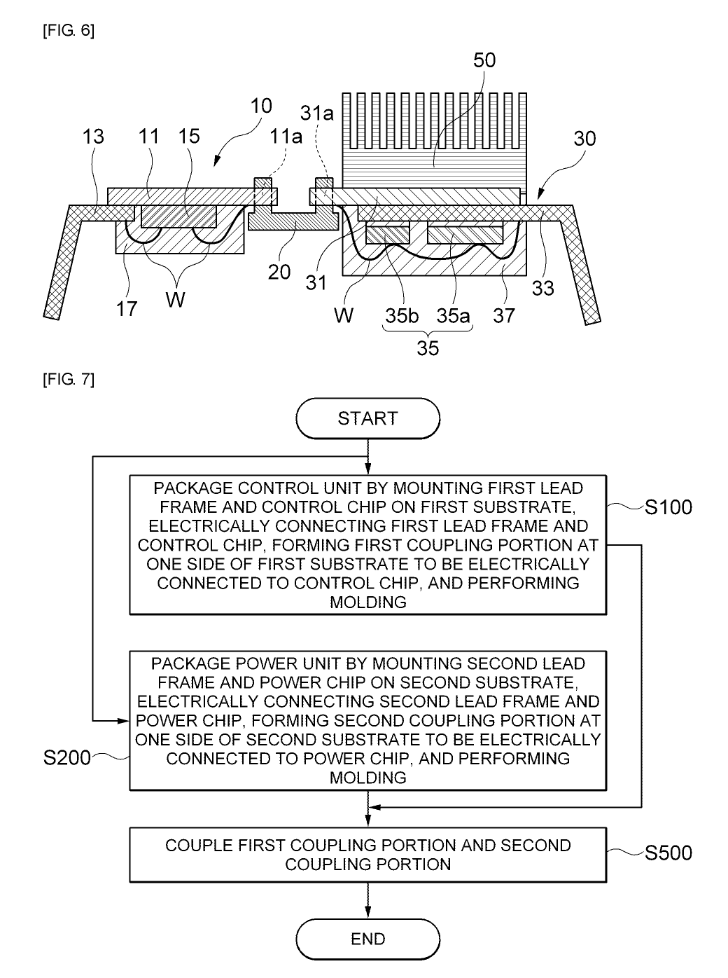

FIG. 1 is a view roughly showing a power device package module in accordance with an embodiment of the present invention. FIG. 2 is a view roughly showing a power device package module in accordance with another embodiment of the present invention. FIG. 3 is a view roughly showing a power device package module in accordance with another embodiment of the present invention. FIG. 4 is a view roughly showing a power device package module in accordance with another embodiment of the present invention. FIG. 5 is a view roughly showing a power device package module in accordance with another embodiment of the present invention. FIG. 6 is a view roughly showing a power device package module in accordance with another embodiment of the present invention.

A power device package module in accordance with an embodiment of the present invention will be described with reference to FIGS. 1 to 3. Referring to FIGS. 1 to 3, a power device package module includes a control unit 10 and a power unit 30. At this time, the control unit 10 and the power unit 30 are coupled after being individually molded.

First, when describing the control unit 10, the control unit 10 includes a first substrate 11, a first lead frame 13, a control chip 15, and a first coupling portion 11a and 13a disposed at one side of the first substrate 11 to be electrically connected to the control chip 15 and is individually molded 17. The first lead frame 13 and the control chip 15 are mounted on one surface of the first substrate 11 so that the control chip 15 is electrically connected to the first lead frame 13. Further, the first coupling portion 11a and 13a is formed at one side of the first substrate 11 to be electrically connected to the control chip 15. In an example, the first lead frame 13 and the control chip 15, and the first coupling portion 11a and 13a and the control chip 15 are connected by wire bonding. In the control unit 10, at least a portion of one surface of the first substrate 11, a portion of the first lead frame 13, and the control chip 15 are molded. At this time, all or a portion of the first coupling portion 11a and 13a and an external connection part of the first lead frame 13 are molded to be exposed outside the molding 17. The control unit 10 is coupled with the power unit 30 through the first coupling portion 11a and 13a exposed outside the molding 17.

When describing the power unit 30, the power unit 30 includes a second substrate 31, a second lead frame 33, a power chip 35, and a second coupling portion 31a, 33a, and 33b disposed at one side of the second substrate 31 to be electrically connected to the power chip 35 and is molded 37 separately from the control unit 10. For example, the power chip 35 may be a device such as an insulated-gate bipolar transistor (IGBT) 35a or a diode. The second lead frame 33 and the power chip 35 are mounted on one surface of the second substrate 31 so that the power chip 35 is electrically connected to the second lead frame 33. In an example, the second lead frame 33 and the power chip 35, and the second coupling portion 31a, 33a, and 33b and the power chip 35 are connected by wire bonding. Further, the second coupling portion 31a, 33a, and 33b is formed at one side of the second substrate 31 to be electrically connected to the power chip 35. In the power unit 30, at least a portion of one surface of the second substrate 31, a portion of the second lead frame 33, and the power chip 35 are molded. At this time, all or a portion of the second coupling portion 31a, 33a, and 33b and an external connection part of the second lead frame 33 are molded to be exposed outside the molding 37. The control unit 10 and the power unit 30, which are individually molded, are coupled through the first coupling portion 11a and 13a and the second coupling portion 31a, 33a, and 33b.

Another embodiment of the present invention will be described. Referring to FIGS. 1 to 6, in an example, the power chip 35 includes the IGBT 35a and a free wheeling diode (FWD) device 35b. The IGBT 35a and the FWD device 35b are individually mounted to be connected in parallel by wire bonding. Normally, in the inverter circuit, the bridge-connected IGBT switches on/off an inductive load to control the load. At this time, in addition to the IGBT, the FWD for rectifying load current is needed.

Further, another embodiment of the present invention will be described. In this embodiment, the first substrate 11 is a PCB substrate. The first lead frame 13 and the control chip 15 are mounted on the PCB substrate. Further, in an example, the first lead frame 13 is attached on the PCB substrate, and the control chip 15 is mounted on the first lead frame 13. And the first lead frame 13 and the first coupling portion 11a and 13a are connected by wire bonding W.

Further, another embodiment of the present invention will be described with reference to FIG. 9. In accordance with this embodiment, the first or second substrate 11 or 31 is formed by forming a seed layer 110 on one surface of a ceramic plate 100 and a metal layer 120 on the seed layer 110. At this time, the first or second lead frame 13 or 33 is attached on the metal layer 120 by soldering, and the control chip 15 or the power chip 35 is mounted on the first or second lead frame 13 or 33. Further, wire bonding is performed between the first lead frame 13 and the first coupling portion 11a and 13a or between the second lead frame 33 and the second coupling portion 31a, 33a, and 33b.

In an example, above mentioned embodiment described with reference to FIG. 9 is applied to the second substrate 31 of the power unit 30. Accordingly, it is possible to greatly improve thermal performance.

Another embodiment of the present invention will be described with reference to FIGS. 4 to 6.

In accordance with an embodiment of the present invention, as shown in FIGS. 4 to 6, a heat sink 50 is attached to the other surface of the second substrate 31 of the power unit 30.

An embodiment of the present invention will be described with reference to FIGS. 3 and/or 6. Referring to FIGS. 3 and/or 6, the power device package module further includes a conductive coupling frame unit 20 which is coupled with the first and second coupling portions 11a, 13a, 31a, 33a, and 33b. The control unit 10 and the power unit 30 are coupled by the coupling frame unit 20.

More specifically, in accordance with another embodiment, one of the first and second coupling portions 11a, 13a, 31a, 33a, and 33b and the coupling frame unit 20 is formed to have a through-hole structure, the other is formed to have a projection structure, and the through-hole structure and the projection structure are coupled with each other. In FIGS. 3 and/or 6, the first and second coupling portions 11a, 13a, 31a, 33a, and 33b are formed to have a through-hole structure, and the coupling frame unit 20 is formed to have a projection structure. In case of the through-hole structure, a through-hole is formed at one side of the first or second substrate 11 or 31, and a conductive material is applied on the inlet-side circumference or the inside of the through-hole to allow electrical connection.

Another embodiment of the present invention will be described with reference to FIGS. 1 and/or 4. Referring to FIGS. 1 and/or 4, one of the first coupling portion 11a and 13a and the second coupling portion 31a, 33a, and 33b is formed to have a through-hole structure, the other is formed to have a projection structure, and the through-hole structure and the projection structure are coupled with each other. In FIGS. 1 and/or 4, although it is shown that the first coupling portion 11a is formed to have a through-hole structure and the second coupling portion 33a is formed to have a projection structure, the opposite is also possible.

Further, referring to FIGS. 1 and/or 4, in an example, a through-hole is formed in the first or second substrate 11 or 31, and a projection structure is a portion of the first or second lead frame 13 or 33. For example, in FIGS. 1 and/or 4, a through-hole is formed in the first substrate 11 to form the first coupling portion 11a, and a projection structure, a portion of the second lead frame 33, forms the second coupling portion 33a.

When describing another embodiment, the portion 13a, 33a, and 33b of the first or second lead frame 13 or 33, which forms a projection structure, forms the region integrated with or separated from the lead frame region electrically connected to the control chip 15 or the power chip 35. For example, in FIGS. 1 and/or 4, although the second coupling portion 33a, which forms a projection structure, is integrally formed with the second lead frame 33, it can be separated from the second lead frame 33. At this time, each of the separated lead frame portions is electrically connected to the control chip 15 or the power chip 35.

Further, another embodiment will be described with reference to FIGS. 2 and/or 5. Referring to FIGS. 2 and/or 5, each of the first and second coupling portions 13a and 33b is a portion of each of the first and second lead frames 13 and 33. At this time, the first and second coupling portions 13a and 33b are bonded by soldering or a conductive material.

In accordance with another embodiment, as shown in FIGS. 2 and/or 5, at least one of the first and second coupling portions 13a and 33b protrudes to the outside to form an external connection terminal. For example, in FIGS. 2 and/or 5, the first coupling portion 13a protrudes to the outside to form an external connection terminal.

Further, in accordance with an embodiment, the first or second coupling portion 13a, 33a, or 33b forms the region integrated with or separated from the lead frame region electrically connected to the control chip 15 or the power chip 35. For example, in FIGS. 2 and/or 5, the first coupling portion 13a forms the region separated from the region of the first lead frame 13 electrically connected to the control chip 15.

Further, when describing another embodiment of the present invention, the control unit 10 and the power unit 30 are connected so that one surface of the first substrate 11 and one surface of the second substrate 31 are disposed in the same or opposite directions. For example, in FIGS. 1, 2, 4, and/or 5, one surface of the first substrate 11 and one surface of the second substrate 31 are disposed in opposite directions, and in FIGS. 3 and/or 6, one surface of the first substrate 11 and one surface of the second substrate 31 are disposed in the same direction.

Next, a method of manufacturing a power device package module in accordance with another aspect of the present invention will be described with reference to the accompanying drawings. In describing or understanding embodiments of this method, description of embodiments of the above-described power device package module will be referred.

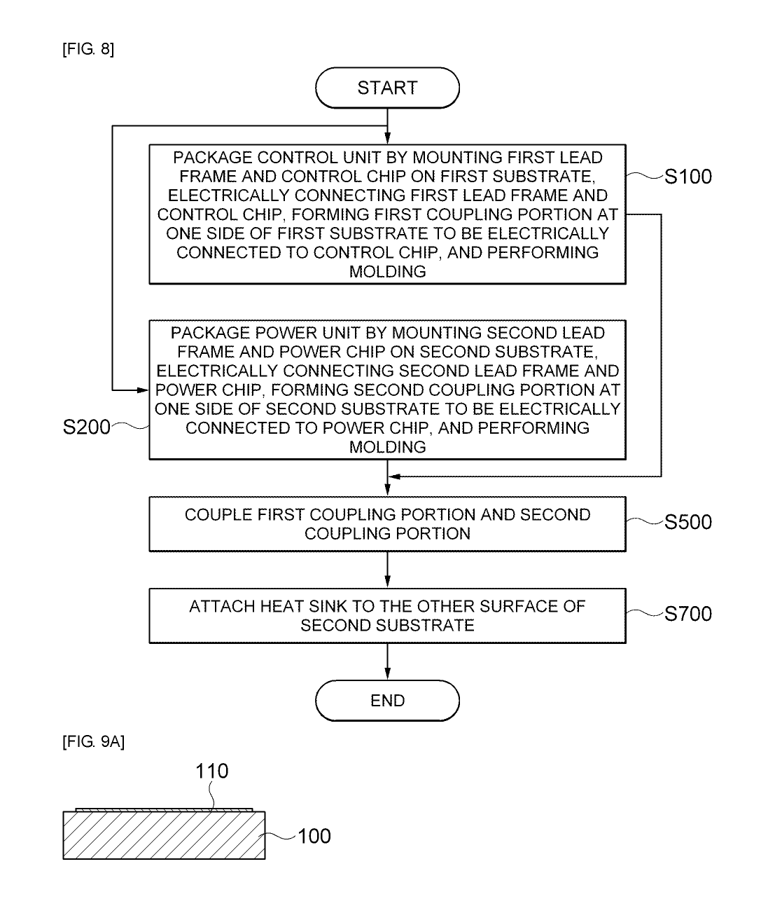

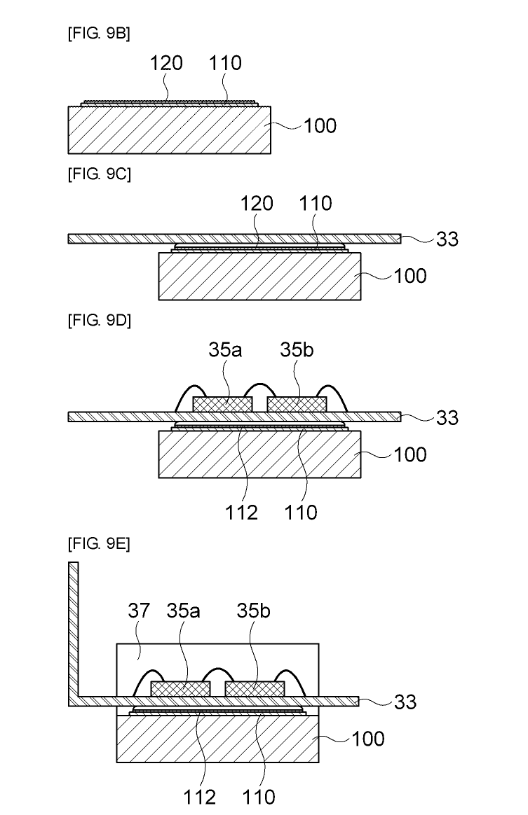

FIG. 7 is a flowchart roughly showing a method of manufacturing a power device package module in accordance with an embodiment of the present invention. FIG. 8 is a flowchart roughly showing a method of manufacturing a power device package module in accordance with another embodiment of the present invention. (a) to (e) of FIG. 9 are views roughly showing a method of manufacturing a power device package module in accordance with an embodiment of the present invention.

An embodiment of the present invention will be described with reference to FIG. 7. A method of manufacturing a power device package module in accordance with this embodiment includes a control unit packaging step, a power unit packaging step, and a connecting step.

First, when describing the control unit packaging step, a first lead frame 13 and a control chip 15 are mounted on one surface of a first substrate 11. At this time, the control chip 15 and the first lead frame 13 are electrically connected to each other. In an example, the control chip 15 and the first lead frame 13 are connected by wire bonding. Further, a first coupling portion 11a and 13a is formed at one side of the first substrate 11 to be electrically connected to the control chip 15. For example, when the first coupling portion 11a has a through-hole structure, a through-hole is formed in the first substrate 11 and a conductive material is applied on the inlet-side or the inside of the through-hole, or when the first coupling portion 11a is integrated with the lead frame, the first coupling portion 11a is formed while mounting the first lead frame 13 on the first substrate 11. When the first coupling portion 13a is a portion of the lead frame or a separate structure separated from the region of the first lead frame 13 electrically connected to the control chip 15, the first coupling portion 13a is formed at one side of the first substrate 11. In the next power unit packaging step, the second coupling portion 31a, 33a, and 33b are the same.

After the first lead frame 13 and the control chip 15 are mounted on the first substrate 11 and connected by wire bonding and the like, at least a portion of one surface of the first substrate 11, a portion of the first lead frame 13, and the control chip 15 are molded 17. As a result of molding, all or a portion of the first coupling portion 11a and 13a and an external connection part of the first lead frame 13 are exposed to the outside.

Further, in an example, referring to (e) of FIG. 9, after molding, a trimming process is performed on the molded portion, and the external connection part of the first lead frame 13 is formed to be bent.

Next, the power unit packaging step will be specifically described. The power unit packaging step and the control unit packaging step may be sequentially performed but performed at the same time in different places. In the power unit packaging step, like the control unit packaging step, a second lead frame 33 and a power chip 35 are mounted on one surface of a second substrate 31. And for example, the power chip 35 is electrically connected to the second lead frame 33 by wire bonding. Further, the second coupling portion 31a, 33a, and 33b is formed at one side of the second substrate 31 to be electrically connected to the power chip 35. At this time, in an example, the second coupling portion 31a, 33a, and 33b is connected to the power chip 35 by wire bonding.

After the second lead frame 33 and the power chip 33 are mounted on the second substrate 31 and connected by wire bonding and the like, at least a portion of one surface of the second substrate 31, a portion of the second lead frame 33, and the power chip 35 are molded 37. At this time, all or a portion of the second coupling portion 31a, 33a, and 33b and an external connection part of the second lead frame 33 are molded to be exposed to the outside.

Further, in an example, referring to (e) of FIG. 9, after molding, a trimming process is performed on the molded portion, and the external connection part of the second lead frame 33 is formed to be bent.

Another embodiment of this manufacturing method will be described. In this embodiment, in the control unit packaging step and the power unit packaging step, wire bonding W is performed to electrically connect between the control chip 15 and the first lead frame 13, between the control chip 15 and the first coupling portion 11a and 13a, between the power chip 35 and the second lead frame 33, and between the power chip 35 and the second coupling portion 31a, 33a, and 33b.

Further, another embodiment of the present invention will be described with reference to FIG. 9.

Referring to FIG. 9, the control unit packaging step or/and the power unit packaging step are performed as follows. First, as shown in (a) of FIG. 9, a seed layer 110 is formed on one surface of a ceramic plate 100, and as shown in (b) of FIG. 9, a metal layer 120 is formed on the seed layer 110. Next, as shown in (c) of FIG. 9, a first or second lead frame 13 or 33 is attached on the metal layer 120 by soldering, and as shown in (d) of FIG. 9, a control chip 15 or a power chip 35 is mounted on the first or second lead frame 13 or 33. Further, as shown in (e) of FIG. 9, molding is performed.

In an example, as shown in (e) of FIG. 9, a forming process (for example, bending) of the lead frame is performed, and a trimming process is performed to remove burrs after molding.

Next, when continuously describing an embodiment shown in FIG. 7, the connecting step is performed. In the connecting step, the packaged control unit 10 and power unit 30 are connected by coupling the first coupling portion 11a and 13a and the second coupling portion 31a, 33a, and 33b.

Another embodiment of this method will be described with reference to FIGS. 3 and/or 6. In the connecting step, the packaged control unit 10 and power unit 30 are connected by coupling a conductive coupling frame unit 20 with the first and second coupling portions 11a and 31a.

Further, another embodiment of this method will be described with reference to FIGS. 1 and/or 4. One of the first coupling portion 11a and 13a and the second coupling portion 31a, 33a, and 33b are formed to have a through-hole structure, and the other is formed to have a projection structure. In the connecting step, the through-hole structure and the projection structure are coupled with each other.

And another embodiment of this method will be described with reference to FIGS. 2 and/or 5. Each of the first and second coupling portions 13a and 33b is a portion of each of the first and second lead frames 13 and 33. In the connecting step, the first and second coupling portions 13a and 33b are bonded by solder paste, a conductive material, and so on. At this time, the first or second coupling portion 13a or 33b may be drawn to the outside. For example, in FIGS. 2 and/or 5, the drawn first coupling portion 13a may support the package module or be used as an external connection terminal.

Further, another embodiment of this method will be described with reference to FIGS. 1 to 6. In the connecting step, the control unit 10 and the power unit 30 are connected so that one surface of the first substrate 11 and one surface of the second substrate 31 may be disposed in the same or opposite directions. For example, in FIGS. 1, 2, 4, and/or 5, one surface of the first substrate 11 and one surface of the second substrate 31 are disposed in opposite directions, and in FIGS. 3 and/or 6, one surface of the first substrate 11 and one surface of the second substrate 31 are disposed in the same direction.

Another embodiment of the present invention will be described with reference to FIG. 8.

Referring to FIG. 8, after the connecting step, a heat sink attaching step of attaching a heat sink 50 to the other surface of the second substrate 31 is further included.

The present invention can obtain a power module by individually packaging a power unit and a control unit through a primary packaging process and connecting the two packages.

The present invention can simplify processes and maximize efficiency by performing assembly according to characteristics of each package compared to the case in which the power unit and the control unit are packaged together in one package.

Further, the present invention can improve productivity by performing assembly through a separate process and maximize characteristics of each package by excluding thermal interaction when the power unit and the control unit are individually packaged.

In addition, it is possible to obtain the following advantages compared to the conventional structure.

First, in terms of reliability and quality, as the power unit and the control unit are individually processed, it is possible to greatly improve thermal performance by separating the power unit, where much heat is generated, from the control unit and intensively using a substrate, which is used for heat radiation, in the power unit according to embodiments. When an assembly process is performed using one package, as many processes are performed, there may be unnecessary much thermal influence between the processes, but when the power unit and the control unit are separated, it is possible to minimize oxidation and thermal stress of a lead frame by bonding the power unit and the control unit after performing only necessary processes.

Second, in terms of implementation of miniaturization and high density, it is possible to reduce the size of the substrate by attaching the heat-radiating substrate only to the power unit according to embodiments. Accordingly, it is possible to maximize use of the lead frame in a design step by separately assembling each part as well as miniaturize the product. Furthermore, through this, it is possible to improve productivity and implement a high density package by maximizing the quantity of manufactured modules per strip.

Third, in terms of yield, when the control unit and the power unit are assembled into a single package, the entire product should treated as bad when failures occur in the power unit or the control unit, but when the control unit and the power unit are bonded after being separately assembled, it is possible to minimize unnecessary yield loss by treating each failed part only, thereby improving yield.

It is apparent that various effects which have not been directly mentioned according to the various embodiments of the present invention can be derived by those skilled in the art from various constructions according to the embodiments of the present invention.

The above-embodiments and the accompanying drawings are provided as examples to help understanding of those skilled in the art, not limiting the scope of the present invention. Therefore, the various embodiments of the present invention may be embodied in different forms in a range without departing from the essential concept of the present invention, and the scope of the present invention should be interpreted from the invention defined in the claims. It is to be understood that the present invention includes various modifications, substitutions, and equivalents by those skilled in the art.

What is claimed is:

1. A power device package module comprising:
a control unit including a first substrate, a first lead frame, a control chip and a first coupling portion and individually molded so that the first coupling portion and an external connection part of the first lead frame are exposed to the outside, wherein a first lead frame and a control chip electrically connected to the first lead frame are mounted on the first substrate and the first coupling portion formed at one side of the first substrate to be electrically connected to the control chip; and
a power unit including a second substrate, a second lead frame, a power chip and a second coupling portion and individually molded so that the second coupling portion and an external connection part of the second lead frame are exposed to the outside, wherein the second lead frame and the power chip electrically connected to the second lead frame are mounted and the second coupling portion formed at one side of the second substrate to be electrically connected to the power chip,
wherein the individually molded control unit and power unit are coupled by the first coupling portion and the second coupling portion.

2. The power device package module according to claim 1, wherein the power unit comprises a heat sink attached to the other surface of the second substrate.

3. The power device package module according to claim 1, further comprising:
a conductive coupling frame unit coupled with the first and second coupling portions, wherein the control unit and the power unit are coupled by the coupling frame unit.

4. The power device package module according to claim 1, wherein one of the first coupling portion and the second coupling portion is formed to have a through-hole structure, the other is formed to have a projection structure, and the through-hole structure and the projection structure are coupled with each other.

5. The power device package module according to claim 4, wherein the through-hole is formed in the first or second substrate, and the projection structure is a portion of the first or second lead frame.

6. The power device package module according to claim 1, wherein each of the first and second coupling portions is a portion of each of the first and second lead frames, and the first and second coupling portions are bonded by soldering.

7. The power device package module according to claim 6, wherein at least one of the first and second coupling portions protrudes to the outside to form an external connection terminal.

8. The power device package module according to claim 1, wherein the control unit and the power unit are connected so that one surface of the first substrate on which the control chip is mounted and one surface of the second substrate on which the power chip is mounted are disposed in the same or opposite directions.

9. The power device package module according to claim 1, wherein the first substrate is a PCB substrate, the first lead frame is attached on the PCB, and the control chip is mounted on the first lead frame, wherein wire bonding is formed between the first lead frame and the first coupling portion.

10. The power device package module according to claim 1, wherein the first or second substrate is formed by forming a seed layer on one surface of a ceramic plate and a metal layer on the seed layer, the first or second lead frame is attached on the metal layer by soldering, and the control chip or the power chip is mounted on the first or second lead frame, wherein wire bonding is formed between the first lead frame and the first coupling portion or between the second lead frame and the second coupling portion.

11. The power device package module according to claim 1, wherein the power chip includes an IGBT device and an FWD device, wherein the IGBT and FWD devices are individually mounted and connected in parallel by wire bonding.

12. The power device package module according to claim 10, wherein the power chip includes an IGBT device and an FWD device, wherein the IGBT and FWD devices are individually mounted and connected in parallel by wire bonding.

13. A method of manufacturing a power device package module comprising:
a control unit packaging step of packaging a control unit by mounting a first lead frame and a control chip on a first substrate, electrically connecting the control chip to the first lead frame, forming a first coupling portion at one side of the first substrate to be electrically connected to the control chip, and individually molding the control unit so that the first coupling portion and an external connection part of the first lead frame are exposed to the outside;
a power unit packaging step of packaging a power unit by mounting a second lead frame and a power chip on a second substrate, electrically connecting the power chip to the second lead frame, forming a second coupling portion at one side of the second substrate to be electrically connected to the power chip, and individually molding the power unit so that the second coupling portion and an external connection part of the second lead frame are exposed to the outside; and
a connecting step of connecting the packaged control unit and power unit by coupling the first coupling portion and the second coupling portion.

14. The method of manufacturing a power device package module according to claim 13, further comprising, after the connecting step,
a heat sink attaching step of attaching a heat sink to the other surface of the second substrate.

15. The method of manufacturing a power device package module according to claim 13, wherein in the connecting step, the packaged control unit and power unit are connected by coupling a conductive coupling frame unit with the first and second coupling portions.

16. The method of manufacturing a power device package module according to claim 13, wherein one of the first coupling portion and the second coupling portion is formed to have a through-hole structure, the other is formed to have a projection structure, and in the connecting step, the through-hole structure and the projection structure are coupled with each other.

17. The method of manufacturing a power device package module according to claim 13, wherein each of the first and second coupling portions is a portion of each of the first and second lead frames, and in the connecting step, the first and second coupling portions are bonded by soldering.

18. The method of manufacturing a power device package module according to claim 13, wherein in the connecting step, the packaged control unit and power unit are connected so that one surface of the first substrate on which the control chip is mounted and one surface of the second substrate on which the power chip is mounted are disposed in the same or opposite directions.

19. The method of manufacturing a power device package module according to claim 13, wherein in the control unit packaging step and the power unit packaging step, wire bonding is performed to electrically connect between the control chip and the first lead frame, between the control chip and the first coupling portion, between the power chip and the second lead frame, and between the power chip and the second coupling portion.

20. The method of manufacturing a power device package module according to claim 19, wherein in the control unit packaging step or the power unit packaging step, a seed layer is formed on one surface of a ceramic plate, a metal layer is formed on the seed layer, the first or second lead frame is attached on the metal layer by soldering, and the control chip or the power chip is mounted on the first or second lead frame.
